(19) United States
(12) Patent Application Publication
(10) Pub. No.: US 2025/0142897 A1
(43) Pub. Date: May 1, 2025

(54) SEMICONDUCTOR DEVICE

(71) Applicant: DB HiTek Co., Ltd., Seoul (KR)

(72) Inventor: Hong Sik SHIN, Bucheon-si (KR)

(73) Assignee: DB HiTek Co., Ltd., Seoul (KR)

(21) Appl. No.: 18/411,747

(22) Filed: Jan. 12, 2024

(30) Foreign Application Priority Data
Oct. 27, 2023 (KR) 10-2023-0145861

(51) Int. Cl. H01L 29/06; H01L 29/78

(52) U.S. Cl. CPC H10D 62/102; H10D 30/603; H10D 62/116

(57) ABSTRACT

A semiconductor device comprising: a substrate; a high side region on the substrate, a drift region surrounding the high side region; an insulating region between the high side region and the drift region, and a first conductive pattern disposed in the insulating region and surrounding the high side region.

### CROSS-REFERENCE TO RELATED APPLICATION

This application claims priority under 35 U.S.C § 119 to Korean Patent Application No. 10-2023-0145861 filed on Oct. 27, 2023, in the Korean Intellectual Property Office, the entire contents of which is hereby incorporated by reference.

### TECHNICAL FIELD

The disclosure relates to a semiconductor device, and more particularly, to a high voltage semiconductor device including an insulating region for securing a high breakdown voltage.

### BACKGROUND

The contents set forth in this section merely provide background information on the present embodiments and do not constitute prior art.

Power semiconductors are widely used in a variety of applications. Devices using power semiconductors are controlled by low-power circuits of tens of volts or lower. These low-voltage circuits can control high-voltage drive circuits of hundreds of volts that provide high-voltage power to other electronic devices. Accordingly, such a circuit can include a low side region and a high side region.

The high side region of an integrated circuit can be electrically insulated from the drift region, which is the low side region, by an insulating junction, thereby limiting the effects of the high voltages on low-voltage elements. In order for a low-voltage control signal to be suitable for high-voltage elements, a low-voltage signal can be level shifted to a higher voltage by a level shift transistor.

In other words, a conventional high-voltage integration circuit may include a high side region and a level shifter. The high side region refers to a region floating at a high voltage, and the level shifter may serve to transmit signals of the low side region to the high side region.

In a semiconductor device including such a high side region, insulation between the high side region and the drift region is important to minimize interference between elements.

The description set forth in the background section should not be assumed to be prior art merely because it is set forth in the background section. The background section may describe aspects or embodiments of the disclosure.

### SUMMARY

It is an object of the present disclosure to provide a semiconductor device that can maintain a high breakdown voltage without increasing the distance between a drift region and a high side region.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

The semiconductor device of the present disclosure can secure an insulation effect without increasing the length of the insulating region by adding an insulating pattern between the drift region and the high side region and insulating them.

Further, the semiconductor device of the present disclosure can block noises introduced from the outside by adding an insulating pattern between the drift region and the high side region and insulating them.

According to some aspects of the disclosure, a semiconductor device includes

a substrate, a high side region on the substrate; a drift region surrounding the high side region, an insulating region between the high side region and the drift region, and a first conductive pattern disposed in the insulating region and surrounding the high side region.

According to some aspects, the first conductive pattern comprises a first conductive well pattern and a first conductive buried layer pattern.

According to some aspects, the first conductive pattern extends within the substrate toward a lower surface of the substrate.

According to some aspects, the drift region comprises at least one element formation region including at least one transistor, and the at least one element formation region is separated from the high side region by the first conductive pattern.

According to some aspects, wherein the drift region comprises at least one element formation region including at least one transistor, the semiconductor device further comprises a second conductive pattern surrounding at least a portion of the element formation region and spaced apart from the first conductive pattern, and at least a portion of the second conductive pattern is disposed in the insulating region.

According to some aspects, the second conductive pattern comprises a second conductive well pattern and a second conductive buried layer pattern.

According to some aspects, the second conductive pattern extends within the substrate toward a lower surface of the substrate.

According to some aspects, the number of the second conductive patterns is plural.

According to some aspects of the disclosure, a semiconductor device includes; a substrate, a high side region on the substrate, a drift region on the substrate, an insulating region between the high side region and the drift region, and a first conductive pattern disposed in the insulating region, extending within the substrate from an upper surface of the substrate toward a lower surface of the substrate, and insulating the high side region and the drift region from each other.

According to some aspects, the first conductive pattern surrounds the high side region, and the drift region is a region surrounding the high side region.

According to some aspects, the first conductive pattern comprises a first conductive well pattern and a first conductive buried layer pattern.

According to some aspects, the drift region comprises at least one element formation region including at least one transistor, and the at least one element formation region is separated from the high side region by the first conductive pattern.

According to some aspects, the drift region comprises at least one element formation region including at least one transistor, the semiconductor device further comprises a second conductive pattern surrounding at least a portion of the element formation region and spaced apart from the first conductive pattern, and at least a portion of the second conductive pattern is disposed in the insulating region.

According to some aspects, the second conductive pattern comprises a second conductive well pattern and a second conductive buried layer pattern.

According to some aspects, the second conductive pattern extends within the substrate toward the lower surface of the substrate.

According to some aspects, the number of the second conductive patterns is plural.

According to some aspects of the disclosure, a semiconductor device includes; a substrate, a high side region on the substrate, a drift region surrounding the high side region, an insulating region between the high side region and the drift region, and a first conductive pattern disposed in the insulating region, surrounding the high side region, and extending within the substrate from an upper surface of the substrate toward a lower surface of the substrate, wherein the first conductive pattern comprises a first conductive buried layer pattern and a first conductive well pattern on the first conductive buried layer pattern.

According to some aspects, the drift region comprises at least one element formation region including at least one transistor, and the at least one element formation region is separated from the high side region by the first conductive pattern.

According to some aspects, the drift region comprises at least one element formation region including at least one transistor, the semiconductor device further comprises a second conductive pattern surrounding at least a portion of the element formation region and spaced apart from the first conductive pattern, and at least a portion of the second conductive pattern is disposed in the insulating region, the second conductive pattern comprises a second conductive well pattern and a second conductive buried layer pattern, and the second conductive pattern extends within the substrate toward the lower surface of the substrate.

According to some aspects, the number of the second conductive patterns is plural.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the contents described above, specific effects of the present disclosure will be described together while describing the following specific details for carrying out the present disclosure.

### BRIEF DESCRIPTION OF THE DRAWINGS

FIG. 1 is a plan view for describing a semiconductor device in accordance with some embodiments of the present disclosure.

FIGS. 2a and 2b are cross-sectional views taken along line A-A′ in FIG. 1.

FIGS. 3a and 3b are cross-sectional views taken along line B-B′ in FIG. 1.

FIG. 4 is a plan view for describing a semiconductor device in accordance with some embodiments of the present disclosure.

FIGS. 5a, 5b, 6a, and 6b are cross-sectional views taken along line C-C′ in FIG. 4.

FIG. 7 is a plan view for describing a semiconductor device in accordance with some embodiments of the present disclosure.

FIGS. 8a and 8b are cross-sectional views taken along line C-C′ in FIG. 7.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

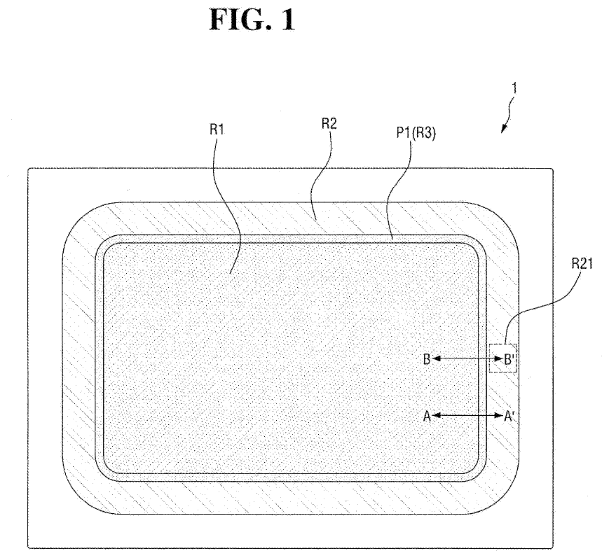

Hereinafter, a semiconductor device in accordance with an embodiment of the present disclosure will be described with reference to FIGS. 1, 2a, 2b, and 3.

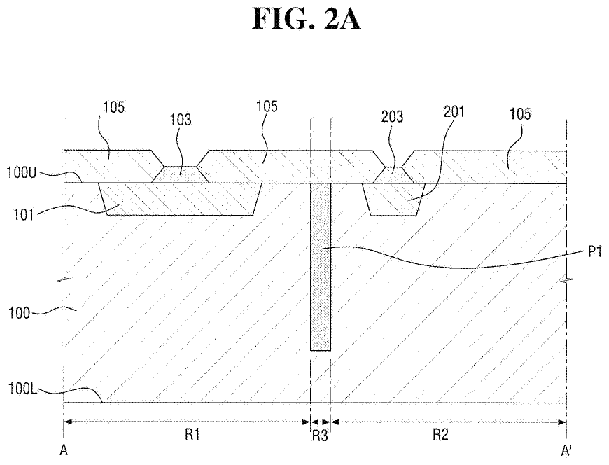

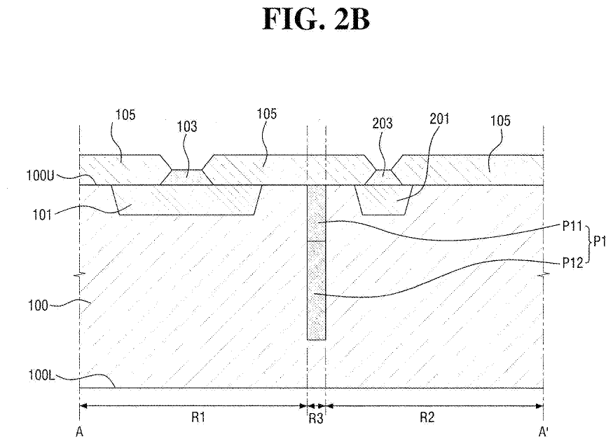

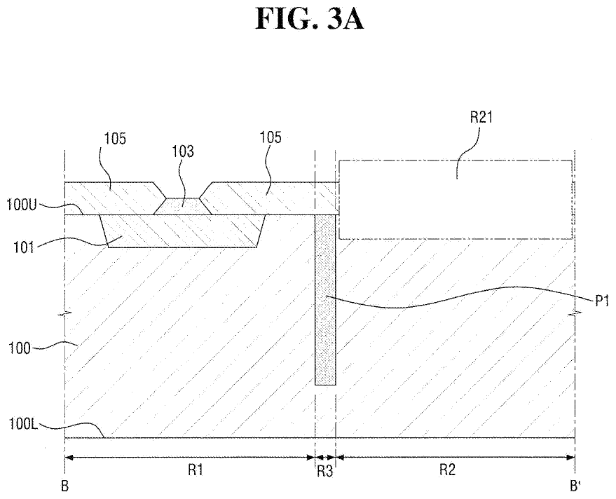

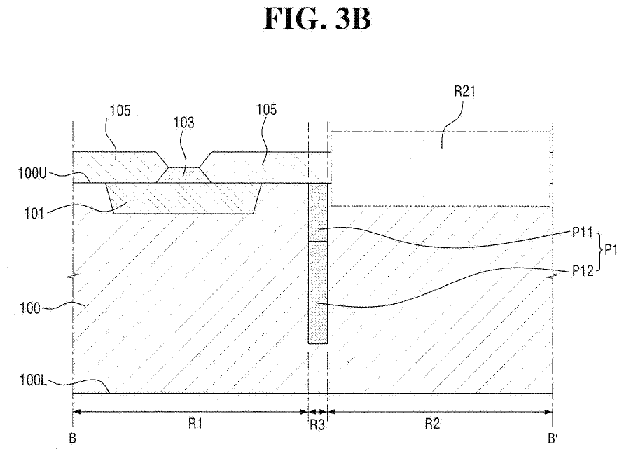

FIG. 1 is a plan view for describing a semiconductor device in accordance with some embodiments of the present disclosure. For clarity of illustration, illustrations of detailed components other than those shown in FIG. 1 are omitted. FIGS. 2a and 2b are cross-sectional views taken along line A-A′ in FIG. 1. FIGS. 3a and 3b are cross-sectional views taken along line B-B′ in FIG. 1.

Referring to FIGS. 1, 2a, 2b, 3a, and 3b, a semiconductor device 1 in accordance with some embodiments of the present disclosure may include a substrate 100, a high side region R1, a drift region R2, and an insulating region R3.

The substrate 100 may be, for example, bulk silicon or silicon-on-insulator (SOI). Alternatively, the substrate 100 may be a silicon substrate, or may include other materials, for example, silicon germanium, indium antimonide, lead telluride, indium arsenide, indium phosphide, gallium arsenide, or gallium antimonide. Or, the substrate 100 may have an epitaxial layer (e.g., an n-type epitaxial layer) formed on a base substrate.

The drift region R2 may surround the high side region R1. The insulating region R3 may be a region between the high side region R1 and the drift region R2. The insulating region R3 may surround the high side region R1.

The high side region R1 on the substrate 100 may include a first well formation region 101. The first well formation region 101 may be p-type and/or n-type. In the drawings, the first well formation area 101 is shown as one, but is not limited thereto. For example, the first well formation region 101 may include at least two regions that are distinct from each other. If the first well formation region 101 includes at least two regions that are distinct from each other, the at least two regions may have different conductivity types. If the first well formation region 101 includes at least two regions that are distinct from each other, the at least two regions may be arranged so as to be insulated from each other.

The high side region R1 may include a first diffusion region 103 on the substrate 100. The first diffusion region 103 may be disposed on the first well formation region 101. The first diffusion region 103 may have the same conductivity type as the first well formation region 101.

For example, if the first well formation region 101 includes at least two regions that are distinct from each other, a diffusion region may be disposed on each of the at least two regions.

An insulating pattern 105 may be disposed on the substrate 100. The insulating pattern 105 may be disposed on the high side region R1, the insulating region R3, and the drift region R2. In some embodiments, a portion of the insulating pattern 105 may be disposed within the substrate 100. The insulating pattern 105 may include an insulating material.

The insulating region R3 may include a first conductive pattern P1. The first conductive pattern P1 may be disposed in the insulating region R3 and surround the high side region R1.

By the first conductive pattern P1, the high side region R1 and the drift region R2 may be separated from each other. By the first conductive pattern P1, the high side region R1 and the drift region R2 may be electrically insulated from each other. At least one element formation region R21 may be separated from the high side region R1 by the first conductive pattern P1. The at least one element formation region R21 may be electrically insulated from the high side region R1 by the first conductive pattern P1.

The first conductive pattern P1 may extend within the substrate 100 from an upper surface 100U of the substrate 100 toward a lower surface 100L of the substrate 100. By the first conductive pattern P1, the high side region R1 and the drift region R2 may be separated and electrically insulated from each other.

The first conductive pattern P1 may include, for example, p-type impurities. At least a portion of the first conductive pattern P1 may be disposed within the n-type epitaxial layer of the substrate 100. Accordingly, a depletion region can be formed by the PN junction, and the drain current flowing from the drift region R2 to the high side region R1 can be blocked.

As shown in FIGS. 2a and 3a, the first conductive pattern P1 in some embodiments may include one pattern. At least a portion of the first conductive pattern P1 may be disposed within the n-type epitaxial layer of the substrate 100.

As shown in FIGS. 2b and 3b, the first conductive pattern P1 in some embodiments may include a first conductive well pattern P11 and a first conductive buried layer pattern P12. The first conductive well pattern P11 may be disposed on the first conductive buried layer pattern P12. Each of the first conductive well pattern P11 and the first conductive buried layer pattern P12 may be of the same conductivity type (e.g., p-type). In the process of forming the first conductive pattern P1, the first conductive buried layer pattern P12 may first be formed on the substrate 100 (e.g., a p-type base substrate). After the first conductive buried layer pattern P12 is formed, an n-doped epitaxial layer may be formed on the front surface of the substrate 100 (e.g., a p-type base substrate). An ion implantation process for forming the first conductive well pattern P11 doped with p-type may be performed on the n-type epitaxial layer at a location corresponding to the location where the first conductive buried layer pattern P12 is formed. Thereafter, when a thermal process is performed on the substrate 100, the first conductive well pattern P11 and the first conductive buried layer pattern P12 may diffuse and come into contact with each other.

The drift region R2 may include at least one element formation region R21. The drift region R2 may include a region where no elements are disposed, as shown in FIG. 2. The at least one element formation region R21 may include at least one transistor, as shown in FIG. 3. Depending on the types of elements being disposed, the arrangement of the components that constitute the elements in the element formation region R21 may vary. For example, an LDMOS, a JFET, a diode, and the like may be disposed in the element formation region R21.

The drift region R2 on the substrate 100 may include a second well formation region 201. The second well formation region 201 may be, for example, n-type. A second diffusion region 203 may be disposed on the second well formation region 201.

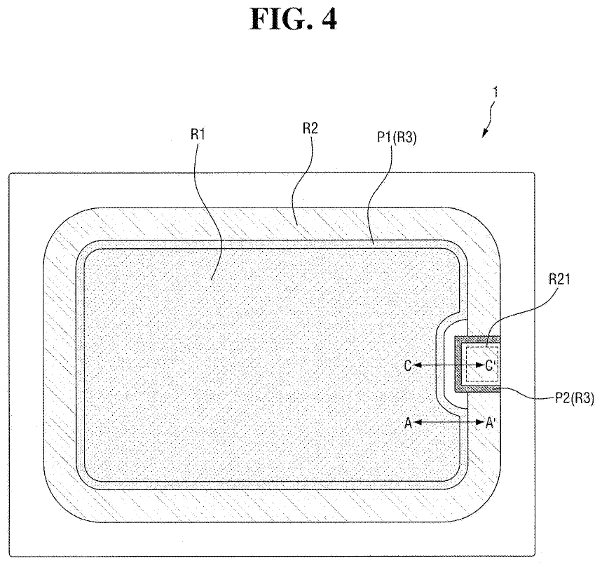

In the following, a semiconductor device in accordance with an embodiment of the present disclosure will be described with reference to FIGS. 4, 5a, 5b, 6a, and 6b. For clarity of description, any description that may otherwise repeat what was described previously will be omitted.

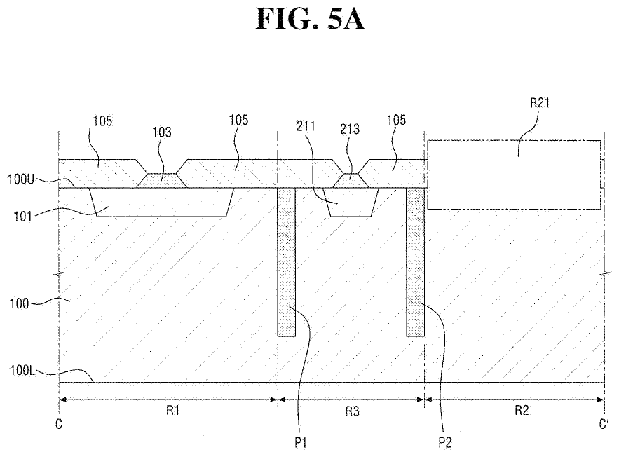

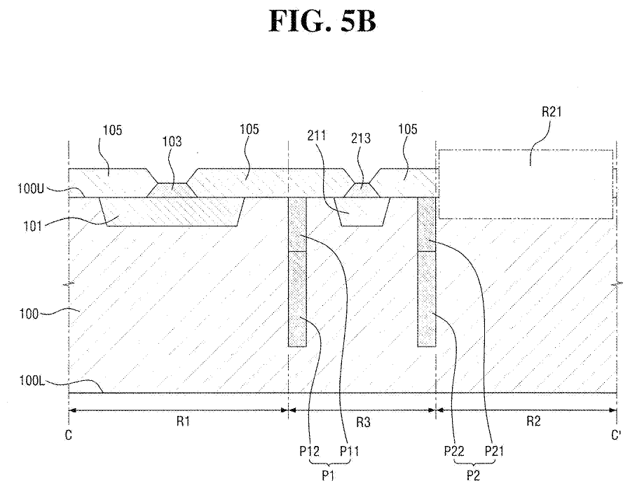

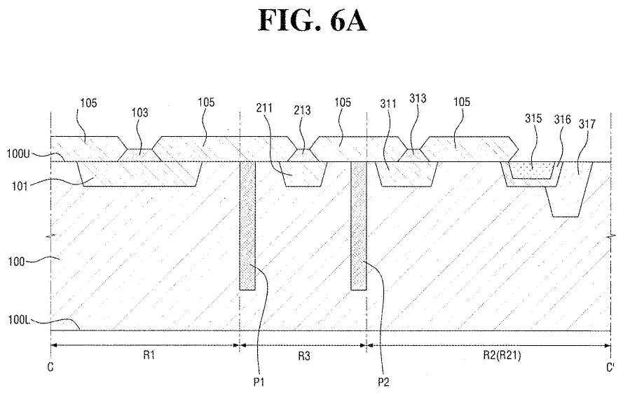

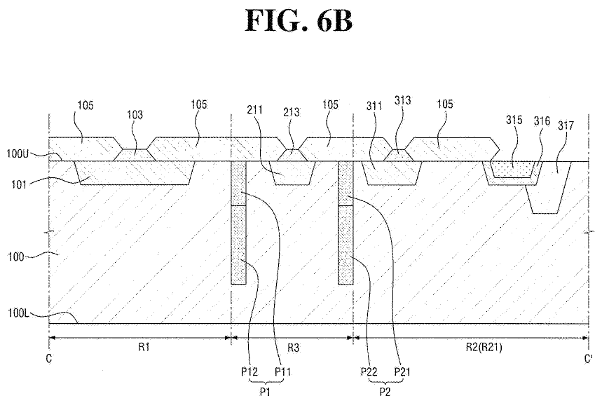

FIG. 4 is a plan view for describing a semiconductor device in accordance with some embodiments of the present disclosure. For clarity of illustration, illustrations of detailed components other than those shown in FIG. 4 are omitted. FIGS. 5a, 5b, 6a, and 6b are cross-sectional views taken along line C-C′ in FIG. 4.

Referring to FIGS. 4, 5a, 5b, 6a, and 6b, the semiconductor device 1 in accordance with some embodiments of the present disclosure may further include a second conductive pattern P2.

The second conductive pattern P2 may surround at least a portion of the element formation region R21. A portion of the second conductive pattern P2 may be disposed in the insulating region R3. The second conductive pattern P2 may be spaced apart from the first conductive pattern P1. A portion of the first conductive pattern P1 may be disposed between the high side region R1 and the second conductive pattern P2. A portion of the first conductive pattern P1 may be disposed along a portion of the second conductive pattern P2 disposed in the insulating region R3, and may be disposed to be spaced apart from the portion of the second conductive pattern P2. The portion of the second conductive pattern P2 disposed in the insulating region R3 may be disposed between the first conductive pattern P1 and the element formation region R21.

By the second conductive pattern P2, the element formation region R21 and the high side region R1 may be separated from each other. By the second conductive pattern P2, the element formation region R21 and the high side region R1 may be electrically insulated from each other.

The second conductive pattern P2 may include, for example, p-type impurities. At least a portion of the second conductive pattern P2 may be disposed in the n-type epitaxial layer of the substrate 100. An insulating region R3 where the first conductive pattern P1, the n-type epitaxial layer of the substrate 100, and the second conductive pattern P2 intersect successively may be disposed. Accordingly, a depletion region can be formed by the PN junction, and the drain current flowing from the drift region R2 to the high side region R1 can be blocked.

As shown in FIGS. 5a and 6a, the second conductive pattern P2 in some embodiments may include one pattern. At least a portion of the second conductive pattern P2 may be disposed within the n-type epitaxial layer of the substrate 100.

As shown in FIGS. 5b and 6b, the second conductive pattern P2 in some embodiments may include a second conductive well pattern P21 and a second conductive buried layer pattern P22. The second conductive well pattern P21 may be disposed on the second conductive buried layer pattern P22. Each of the second conductive well pattern P21 and the second conductive buried layer pattern P22 may be of the same conductivity type (e.g., p-type). In the process of forming the first conductive pattern P1 described above, the second conductive pattern P2 may also be formed together.

An element including at least one transistor may be formed in the element formation region R21. For example, as shown in FIG. 6, a particular element may be disposed in the element formation region R21. The element formation region R21 shown in FIG. 6 illustrates a portion of an LDMOS.

In the example of FIG. 6, the substrate 100 in the element formation region R21 may include a fourth well formation region 311. The fourth well formation region 311 may include, for example, n-type impurities. A fourth diffusion region 413 may be disposed on the fourth well formation region 311. The fourth diffusion region 413 may be disposed on the substrate 100 in the element formation region R21. The fourth diffusion region 413 may have the same conductivity type as the fourth well formation region 311.

The substrate 100 in the element formation region R21 may include a fifth diffusion region 315, a sixth diffusion region 316 surrounding the fifth diffusion region 315, and a seventh diffusion region 317. The fifth diffusion region 315 may include, for example, n-type impurities. The sixth diffusion region 316 and the seventh diffusion region 317 may include, for example, p-type impurities.

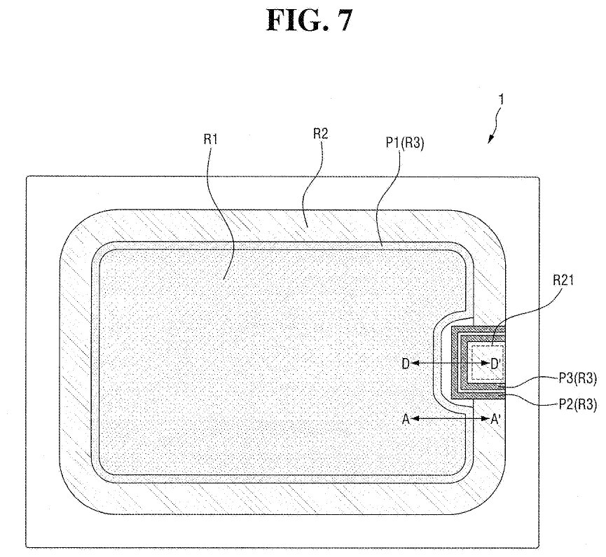

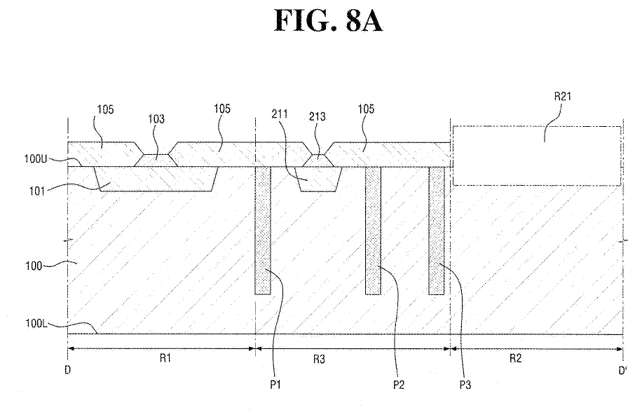

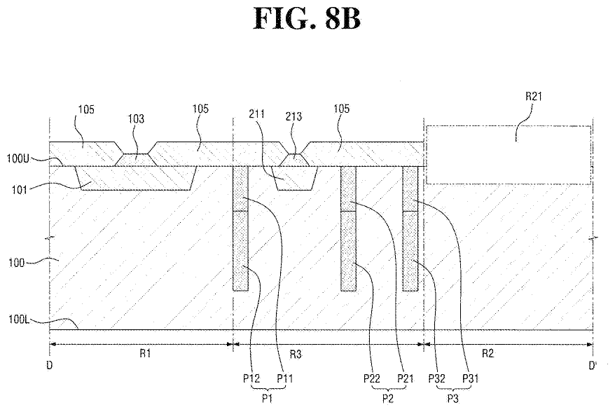

In the following, a semiconductor device in accordance with an embodiment of the present disclosure will be described with reference to FIGS. 7, 8a, and 8b. For clarity of description, any description that may otherwise repeat what was described previously will be omitted.

FIG. 7 is a plan view for describing a semiconductor device in accordance with some embodiments of the present disclosure. For clarity of illustration, illustrations of detailed components other than those shown in FIG. 7 are omitted. FIGS. 8a and 8b are cross-sectional views taken along line C-C′ in FIG. 7.

Referring to FIGS. 7, 8a, and 8b, the semiconductor device 1 in accordance with some embodiments of the present disclosure may further include a third conductive pattern P3. For example, the semiconductor device 1 may further include a plurality of conductive patterns (e.g., a second conductive pattern P2 and a third conductive pattern P3) surrounding the element formation region, in addition to the first conductive pattern P1 surrounding the high side region R1.

The third conductive pattern P3 may surround at least a portion of the element formation region R21. A portion of the third conductive pattern P3 may be disposed in the insulating region R3. The third conductive pattern P3 may be spaced apart from each of the first conductive pattern P1 and the second conductive pattern P2. A portion of the third conductive pattern P3 may be disposed between a portion of the second conductive pattern P2 and the element formation region R21.

By the third conductive pattern P3, the element formation region R21 and the high side region R1 may be separated from each other. By the third conductive pattern P3, the element formation region R21 and the high side region R1 may be electrically insulated from each other.

The third conductive pattern P3 may include, for example, p-type impurities. At least a portion of the third conductive pattern P3 may be disposed within the n-type epitaxial layer of the substrate 100. An insulating region R3 where the first conductive pattern P1, the n-type epitaxial layer of the substrate 100, the second conductive pattern P2, and the third conductive pattern P3 intersect successively may be disposed. Accordingly, a depletion region can be formed by the PN junction, and the drain current flowing from the drift region R2 to the high side region R1 can be blocked.

As shown in FIG. 8a, the third conductive pattern P3 in some embodiments may include one pattern. At least a portion of the third conductive pattern P3 may be disposed within the n-type epitaxial layer of the substrate 100.

As shown in FIG. 8b, the third conductive pattern P3 in some embodiments may include a third conductive well pattern P31 and a third conductive buried layer pattern P32. The third conductive well pattern P31 may be disposed on the third conductive buried layer pattern P32. Each of the third conductive well pattern P31 and the third conductive buried layer pattern P32 may be of the same conductivity type (e.g., p-type). In the process of forming the first conductive pattern P1 described above, the second conductive pattern P2 and the third conductive pattern P3 may also be formed together.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor device comprising:
a substrate;
a high side region on the substrate;
a drift region surrounding the high side region;
an insulating region between the high side region and the drift region; and
a first conductive pattern disposed in the insulating region and surrounding the high side region.

2. The semiconductor device of claim 1, wherein the first conductive pattern comprises a first conductive well pattern and a first conductive buried layer pattern.

3. The semiconductor device of claim 2, wherein the first conductive pattern extends within the substrate toward a lower surface of the substrate.

4. The semiconductor device of claim 1, wherein the drift region comprises at least one element formation region including at least one transistor, and
the at least one element formation region is separated from the high side region by the first conductive pattern.

5. The semiconductor device of claim 1, wherein the drift region comprises at least one element formation region including at least one transistor,
the semiconductor device further comprises a second conductive pattern surrounding at least a portion of the element formation region and spaced apart from the first conductive pattern, and
at least a portion of the second conductive pattern is disposed in the insulating region.

6. The semiconductor device of claim 5, wherein the second conductive pattern comprises a second conductive well pattern and a second conductive buried layer pattern.

7. The semiconductor device of claim 6, wherein the second conductive pattern extends within the substrate toward a lower surface of the substrate.

8. The semiconductor device of claim 5, wherein the number of the second conductive patterns is plural.

9. A semiconductor device comprising:
a substrate;
a high side region on the substrate;
a drift region on the substrate;
an insulating region between the high side region and the drift region; and
a first conductive pattern disposed in the insulating region, extending within the substrate from an upper surface of the substrate toward a lower surface of the substrate, and insulating the high side region and the drift region from each other.

10. The semiconductor device of claim 9, wherein the first conductive pattern surrounds the high side region, and
the drift region is a region surrounding the high side region.

11. The semiconductor device of claim 9, wherein the first conductive pattern comprises a first conductive well pattern and a first conductive buried layer pattern.

12. The semiconductor device of claim 9, wherein the drift region comprises at least one element formation region including at least one transistor, and
the at least one element formation region is separated from the high side region by the first conductive pattern.

13. The semiconductor device of claim 9, wherein the drift region comprises at least one element formation region including at least one transistor,
the semiconductor device further comprises a second conductive pattern surrounding at least a portion of the element formation region and spaced apart from the first conductive pattern, and
at least a portion of the second conductive pattern is disposed in the insulating region.

14. The semiconductor device of claim 13, wherein the second conductive pattern comprises a second conductive well pattern and a second conductive buried layer pattern.

15. The semiconductor device of claim 14, wherein the second conductive pattern extends within the substrate toward the lower surface of the substrate.

16. The semiconductor device of claim 13, wherein the number of the second conductive patterns is plural.

17. A semiconductor device comprising:
a substrate;
a high side region on the substrate;
a drift region surrounding the high side region;
an insulating region between the high side region and the drift region; and
a first conductive pattern disposed in the insulating region, surrounding the high side region, and extending within the substrate from an upper surface of the substrate toward a lower surface of the substrate,
wherein the first conductive pattern comprises a first conductive buried layer pattern and a first conductive well pattern on the first conductive buried layer pattern.

18. The semiconductor device of claim 17, wherein the drift region comprises at least one element formation region including at least one transistor, and
the at least one element formation region is separated from the high side region by the first conductive pattern.

19. The semiconductor device of claim 17, wherein the drift region comprises at least one element formation region including at least one transistor,
the semiconductor device further comprises a second conductive pattern surrounding at least a portion of the element formation region and spaced apart from the first conductive pattern, and
at least a portion of the second conductive pattern is disposed in the insulating region,
the second conductive pattern comprises a second conductive well pattern and a second conductive buried layer pattern, and
the second conductive pattern extends within the substrate toward the lower surface of the substrate.

20. The semiconductor device of claim 19, wherein the number of the second conductive patterns is plural.
